(19) United States
(12) Patent Application Publication
(10) Pub. No.: US 2020/0185345 A1
(43) Pub. Date: Jun. 11, 2020

(54) SEMICONDUCTOR DEVICE

(71) Applicant: NANYA TECHNOLOGY CORPORATION, New Taipei City (TW)

(72) Inventor: Chun-Cheng LIAO, New Taipei City (TW)

(21) Appl. No.: 16/283,292

(22) Filed: Feb. 22, 2019

Related U.S. Application Data
(60) Provisional application No. 62/776,548, filed on Dec. 7, 2018.

(51) Int. Cl. H01L 23/00; H01L 21/768; H01L 23/48

(52) U.S. Cl. CPC H01L 24/14; H01L 21/76898; H01L 23/481; H01L 24/11; H01L 24/13; H01L 21/30625; H01L 2224/1146; H01L 21/76843; H01L 2224/1182; H01L 2224/11912; H01L 24/16

(57) ABSTRACT

The present disclosure relates to a semiconductor device. The semiconductor device includes a semiconductor substrate, a conductive through electrode, an insulating film, a bump and a connection layer, wherein the connection layer comprises a patternable material with conductive particles. The conductive through electrode penetrates through the semiconductor substrate. The patternable material comprises photosensitive material. The photosensitive material is a photoresist or polyimide. The conductive particles comprise copper (Cu), nickel (Ni), gold (Au), or silver (Ag). The connection layer is formed by spin coating, CVD (chemical vapor deposition) process or PVD (physical vapor deposition) process. The insulating film surrounds the conductive through electrode and electrically isolates the conductive through electrode from the is substrate. The bump is disposed over the conductive through electrode. The connection layer is disposed over the bump.

### PRIORITY CLAIM AND CROSS-REFERENCE

This application claims the priority benefit of U.S. provisional application Ser. No. 62/776,548, filed on Dec. 7, 2018. The entirety of the above-mentioned patent application is hereby incorporated by reference herein and made a part of this specification.

### TECHNICAL FIELD

The present disclosure relates to a semiconductor device, and more particularly, to a semiconductor device having a conductive through electrode and a connection layer of patternable material with conductive particles.

### DISCUSSION OF THE BACKGROUND

Two-dimensional (2D) approaches have been traditionally applied for IC integration. Continuous demand for new IC packages that can fulfill the consumer market requirements for increased functionality and performance with reduced size and cost has driven the semiconductor industry to develop more innovative packaging, using vertical, three-dimensional (3D) integration.

General advantages of 3D packaging technologies include form factor miniaturization (reduction of size and weight), integration of heterogeneous technologies in a single package, replacement of lengthy 2D interconnects with short vertical interconnects, and the reduction of power consumption.

High data reliability, high speed of memory access, lower power consumption and reduced chip size are features that are demanded from semiconductor memory. In recent years, three-dimensional (3D) memory devices formed by vertically stacking laminated semiconductor chips and interconnecting the semiconductor chips using through-silicon vias (TSVs) have been introduced. The TSVs are through electrodes that penetrate a semiconductor chip including a semiconductor substrate typically composed of silicon. Benefits of the 3D memory devices include stacking of a plurality of chips with a large number of vertical vias between the plurality of chips and the memory controller, which allows wide bandwidth buses with high transfer rates between functional blocks in the plurality of chips and a considerably smaller footprint. Thus, the 3D memory devices contribute to large memory capacity, higher memory access speed and chip size reduction. The 3D memory devices include Hybrid Memory Cube (HMC) and High Bandwidth Memory (HBM).

Vias on the 3D memory devices may be formed by a “via middle” process. For example, the process may include 1) disposing front bumps on a front surface of a semiconductor device; 2) thinning a back surface of a silicon substrate and exposing copper through-silicon vias by “Si reveal etching” during wafer processing (e.g., between transistor formation and a wiring process); 3) depositing a dielectric film, and 4) polishing the dielectric film by chemical mechanical planarization (CMP) to form back bumps. The via middle process described above, especially the exposing of copper through-silicon vias and polishing of the dielectric film by CMP, may incur significant manufacturing costs. During the manufacturing process, several issues may arise, including irregularity of the back surface processing due to wafer warpage, inconsistency of heights of the copper through-silicon vias due to Si reveal etching, failures in exposing the copper through-silicon vias when a process window of the CMP is reduced, and scratches, cracks, and other defects formed on a silicon board when the process window of the CMP is increased.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device includes a semiconductor substrate, a conductive through electrode, an insulating film, a bump and a connection layer, wherein the connection layer comprises a patternable material with conductive particles. The conductive through electrode penetrates through the semiconductor substrate. The insulating film surrounds the conductive through electrode and electrically isolates the conductive through electrode from the substrate. The bump is disposed over the conductive through electrode. The connection layer is disposed over the bump.

In some embodiments, the patternable material comprises photosensitive material.

In some embodiments, the photosensitive material is a photoresist or polyimide.

In some embodiments, the conductive particles comprise copper (Cu), nickel (Ni), gold (Au), or silver (Ag).

In some embodiments, the connection layer is formed by spin coating, CVD (chemical vapor deposition) process or PVD (physical vapor deposition) process.

In some embodiments, the conductive through electrode comprises a first portion, a second portion and a third portion. The first portion is arranged in the semiconductor substrate. The second portion protrudes vertically from the first portion. The third portion protrudes laterally from the second portion and the third portion includes a side surface to define a width of the third portion.

In some embodiments, the third portion of the conductive through electrode is tapered to form the side surface of the third portion in a slanted manner.

In some embodiments, the third portion of the conductive through electrode is tapered toward a side opposite to the first portion of the conductive through electrode.

In some embodiments, a width of the second portion of the conductive through electrode is substantially the same as a width of the first portion of the conductive through electrode, wherein the width of the third portion of the conductive through electrode is greater than a width of each of the first and second portions.

In some embodiments, the second portion, the third portion and the semiconductor substrate form a gap therebetween.

In some embodiments, the first, second and third portions of the conductive through electrode are formed of the same material.

In some embodiments, the insulating film comprises a first part, a second part and a third part. The first part is interposed between the first portion and the semiconductor substrate. The second part is arranged in the gap. The third part protrudes from the second part to cover a part of the side surface of the third portion.

In some embodiments, a remaining part of the side surface of the third portion is not covered by the third part.

In some embodiments, the first part of the insulating film has a first thickness between the first portion of the conductive through electrode and the substrate, and the second part of the insulating film has a second thickness between the third portion of the conductive through electrode and the semiconductor substrate, wherein the second thickness is greater than the first thickness.

In some embodiments, the third part of the insulating film protrudes from the second part of the insulating film with a third thickness to cover the part of the side surface of the third portion of the conductive through electrode, wherein the third thickness is smaller than the second thickness of the second part of the insulating film.

In some embodiments, the first part of the insulating film comprises a first insulating layer and a first insulating liner, the second part of the insulating film comprises a second insulating layer and a second insulating liner, and the third part of the insulating film comprises a third insulating liner, wherein the second insulating liner is continuous with the first and third insulating liners.

In some embodiments, the first part of the insulating film further comprises a fourth insulating liner between the first insulating liner and the first portion of the conductive through electrode, wherein the second part of the insulating film further comprises a fifth insulating liner between the second insulating liner and the second portion of the conductive through electrode, wherein the third part of the insulating film further comprises a sixth insulating liner between the third insulating liner and the third portion of the conductive through electrode, and wherein the fifth insulating liner is continuous with the fourth and sixth insulating liners.

In some embodiments, the first insulating layer has a first thickness between the first insulating liner and the substrate, and the second insulating layer has a second thickness between the third portion of the conductive through electrode and the substrate, the second thickness being greater than the first thickness.

In some embodiments, each of the first, second and third insulating liners comprises a silicon nitride film, and each of the fourth, fifth and sixth insulating liners comprises a silicon oxide film.

In some embodiments, the silicon nitride film is thicker than the silicon oxide film.

Another aspect of the present disclosure provides an electronic unit. The electronic unit includes at least two of the above-mentioned semiconductor devices. The third portion of the conductive through electrode of one semiconductor device is electrically connected to the bump of the other semiconductor device through the connection layer. The connection layer is patterned over the bump of the other semiconductor.

With the above-mentioned configurations of the semiconductor device, a parasitic capacitance of the through silicon via structure is reduced because the conductive lines are separated from each other by the insulation layer, and the speed of the signal transmission through the through silicon via structure is thus increased.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a schematic diagram of through electrodes in a semiconductor device, in accordance with an embodiment of the present disclosure.

FIG. 2 is a schematic diagram of a portion of a through electrode in a semiconductor device, in accordance with an embodiment of the present disclosure.

FIG. 3 is a cross-sectional schematic view of a semiconductor device before dry etching for formation of through electrodes, in accordance with an embodiment of the present disclosure.

FIG. 4 is a cross-sectional schematic view of the semiconductor device after dry etching for formation of conductive through electrodes, in accordance with an embodiment of the present disclosure.

FIG. 5 is a cross-sectional schematic view of the semiconductor device after depositing of an outer liner in an opening, in accordance with an embodiment of the present disclosure.

FIG. 6 is a cross-sectional schematic view of the semiconductor device after etching of the SiO layer of the SOI (silicon on insulator), in accordance with an embodiment of the present disclosure.

FIG. 7 is a cross-sectional schematic view of the semiconductor device after etching of the exposed Si layer 11c, in accordance with an embodiment of the present disclosure.

FIG. 8 is a schematic cross-sectional view of the semiconductor device after formation of an inner liner on an inner wall of the opening, a cavity and a barrier film, in accordance with an embodiment of the present disclosure.

FIG. 9 is a schematic cross-sectional view of the semiconductor device after applying a conductive material in the opening and the cavity, in accordance with an embodiment of the present disclosure.

FIG. 10 is a schematic cross-sectional view of the semiconductor device after removal of the copper from the barrier film, in accordance with an embodiment of the present disclosure.

FIG. 11 is a schematic cross-sectional view of the semiconductor device after formation of a photoresist for some front bumps, in accordance with an embodiment of the present disclosure.

FIG. 12 is a schematic cross-sectional view of the semiconductor device after formation of front bumps 16, in accordance with an embodiment of the present disclosure.

FIG. 13 is a schematic cross-sectional view of the semiconductor device after applying a temporary carrier on the semiconductor device, in accordance with an embodiment of the present disclosure.

FIG. 14 is a schematic cross-sectional view of through electrodes in a semiconductor device after removal of a portion of the SOI, in accordance with an embodiment of the present disclosure.

FIG. 15 is a schematic cross-sectional view of through electrodes in a semiconductor device after exposure of back bumps by Si revealing dry etching and dielectric film over-etching, in accordance with an embodiment of the present disclosure.

FIG. 16 is a schematic cross-sectional view of through electrodes in a stacked pair of semiconductor devices of an electronic unit after each back bump is physically connected to a corresponding front bump via the connection layer, in accordance with an embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

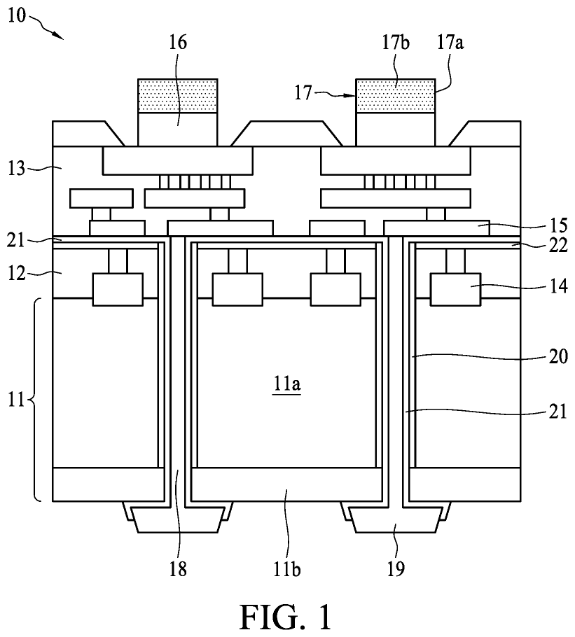

FIG. 1 is a schematic diagram of through electrodes in a semiconductor device 10, in accordance with an embodiment of the present disclosure. FIG. 1 may be a cross-sectional view of the semiconductor device 10 including a semiconductor substrate 11, an element region 12 and a wiring region 13. In some embodiments, the semiconductor substrate 11 may be silicon on insulator (SOI). In some embodiments, the semiconductor device 10 may be a chip. In some embodiments, the SOI 11 may include a layer 11a made of silicon (e.g., a Si layer or a semiconductor layer) and a layer 11b made of silicon oxide (e.g., a SiO layer or an insulative layer). In some embodiments, the SOI 11 may include another layer 11c made of silicon in direct contact with and on a surface of the layer 11b opposite to a surface in direct contact with the layer 11a. The layer 11c made of silicon in direct contact with and on a surface of the layer 11b opposite to a surface in direct contact with the layer 11a may have been removed during or before finalizing a process of manufacturing the semiconductor device 10. The element region 12 may be formed on the layer 11a of the SOI 11. The wiring region 13 may be formed on the element region 12. In some embodiments, the element region 12 may include one or more circuit elements 14. In some embodiments, the wiring region 13 may include wirings 15. Front bumps 16 may be formed on the wiring region 13. A connection layer 17 may be formed on each front bump 16. In some embodiments, the connection layer 17 comprises a patternable material 17a with conductive particles 17b. The patternable material may comprise photosensitive material. The photosensitive material may be a material such as photoresist or polyimide. The conductive particles may comprise copper (Cu), nickel (Ni), gold (Au), or silver (Ag), but the disclosure is not limited thereto. In some embodiments, the connection layer is formed by spin coating, CVD (chemical vapor deposition) process or PVD (physical vapor deposition) process, but the disclosure is not limited thereto.

Around each through electrode 18, an inner liner 21 and an outer liner 20 may be formed as insulating films between the through electrode 18 and the SOI 11. In some embodiments, the inner liner 21 and the outer liner 20 may be formed as a circular type cylinder, a square type cylinder or a polygonal type cylinder. In some embodiments, the inner liner 21 may be formed by anisotropic etching on the SOI 11. In some embodiments, the outer liner 20 may be implemented by silicon oxide (SiO). The inner liner 21 may prevent copper included in the through electrode 18 from diffusing into the Si layer 11a. The outer liner 20 may function as a protective film of the Si layer 11a while a cavity is being formed, as will be described later in this disclosure.

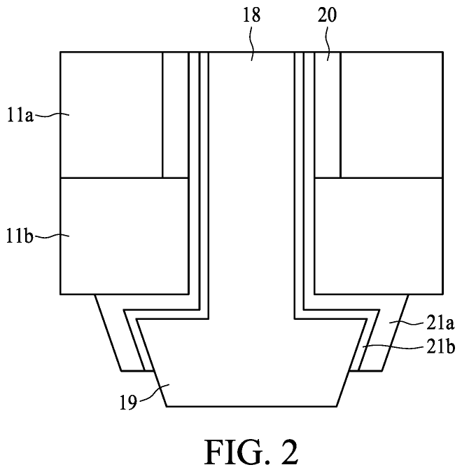

FIG. 2 is a schematic diagram of a portion of a through electrode 18 in a semiconductor device 10, in accordance with an embodiment of the present disclosure. A through electrode 18 may be formed through layers 11a and 11b of a SOI 11. In some embodiments, a back bump 19 protruding from the SOI 11 may be exposed by dry etching. In some embodiments, a cross-sectional width of the portion of the through electrode 18 in the Si layer 11a in the SOI 11 may be smaller than a cross-sectional width of the back bump 19. In some embodiments, an outer liner 20 may be formed within the Si layer 11a of the SOI 11. In some embodiments, an inner liner 21 may extend to a side surface of each back bump 19. In some embodiments, a part of the inner liner 21 is disposed on the side surface of the back bump 19 as a sidewall spacer. In some embodiments, the inner liner 21 may include a layer 21a made of silicon nitride (SiN) that is in direct contact with the outer liner 20 and a layer 21b made of silicon oxide (SiO) that is in direct contact with the through electrode 18 in the SOI 11. The inner liner 21 may extend to at least a portion of the side surface of the back bump 19. Thus, the conductive through electrode 18 may include a first portion through a semiconductor substrate (e.g., the Si layer 11a), a second portion protruding vertically from the first portion, and a third portion 19 (back bump) protruding laterally from the second portion. Therefore, the second portion, the third portion and the semiconductor substrate form a gap therebetween, and the insulating film (11b, 20, 21a, 21b), that is formed to isolate the through electrode 18 from the Si layer 11a, includes a first part between the first portion of the electrode 18 and the semiconductor substrate (or Si layer 11a), a second part in the gap between the second and third portions of the electrode 18 and the semiconductor substrate, and a third part (respective parts of the 21a and 21b) protruding from the second part to cover a part of a side surface of the third portion while leaving a remaining part of the side surface of the third portion uncovered.

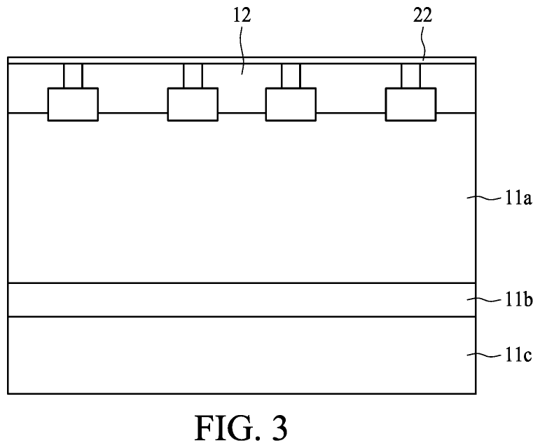

FIG. 3 is a schematic diagram of a semiconductor device 10, in accordance with an embodiment of the present disclosure. FIG. 3 may be a cross-sectional view of the semiconductor device 10 before dry etching for formation of through electrodes. The semiconductor device 10 may include a semiconductor substrate (SOI) 11 including Si layers 11a and 11c and a SiO layer 11b between the Si layers 11a and 11c, an element region 12 and a barrier film 22. In some embodiments, the element region 12 may be formed on a surface of the Si layer 11a, opposite to a surface in direct contact with the SiO layer 11b. In some embodiments, a thickness of the Si layer 11a may be approximately 2.5 μm, a thickness of the SiO layer 11b may be approximately 20 μm, and a thickness of the element region 12 may be approximately 20 μm. In some embodiments, the barrier film 22 may be formed on the element region 12. The barrier film 22 may serve as a prevention film of copper diffusion and as an etch stop film. In some embodiments, the barrier film 22 may include silicon nitride (SiN), silicon carbon (SiC) and/or silicon nitride (SiN), but the disclosure is not limited thereto.

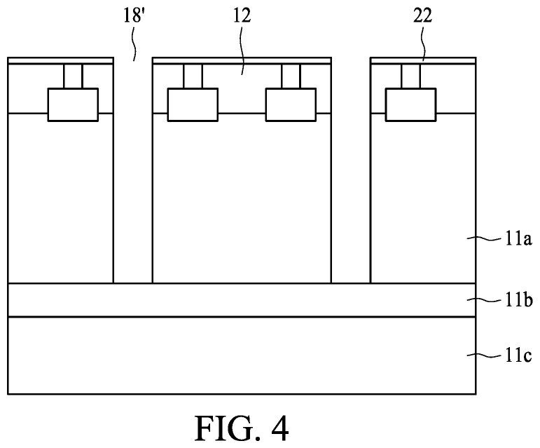

FIG. 4 is a schematic diagram of the semiconductor device 10, in accordance with an embodiment of the present disclosure. FIG. 4 may be a cross-sectional view of the semiconductor device 10 after dry etching for formation of conductive through electrodes. Dry etching for through electrodes formation may be performed through the barrier film 22, the element region 12 and the Si layer 11a. Therefore, an opening 18′ for the through electrode 18 may be formed through the barrier film 22, the element region 12 and the Si layer 11a by a dry etching method. In some embodiments, a Bosch method may be used for dry etching while opening the Si layer 11a. In some embodiments, sulfur hexafluoride (SF₆) gas may be used for etching and octafluorocyclobutane (C₄F₈) gas may be used for polymer deposition. In some embodiments, through electrodes may be formed by the via middle method as shown in FIG. 4, or by other processes, such as a “via first” method.

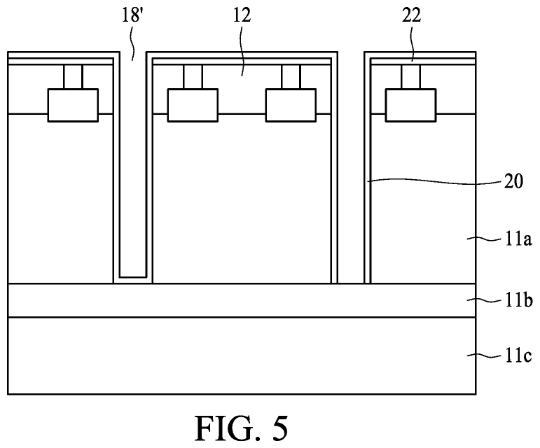

FIG. 5 is a schematic diagram of the semiconductor device 10, in accordance with an embodiment of the present disclosure. FIG. 5 may be a cross-sectional view of the semiconductor device 10 after depositing an outer liner 20 in the opening 18′. In some embodiments, the outer liner 20 may be a SiO layer and deposited at approximately 350 to 500° C. A thickness of the outer liner 20 may be approximately 1 μm. In this process, a SiO film or a laminate film including a SiO layer and a SiN layer may be used. In some embodiments, the laminate film may include the SiO layer having a thickness of approximately 0.3 μm and a SiN layer having a thickness of approximately 0.7 μm. In some embodiments, the laminate film may include a SiO layer having a thickness of approximately 0.7 μm and a SiN layer having a thickness of approximately 0.3 μm, but the disclosure is not limited thereto.

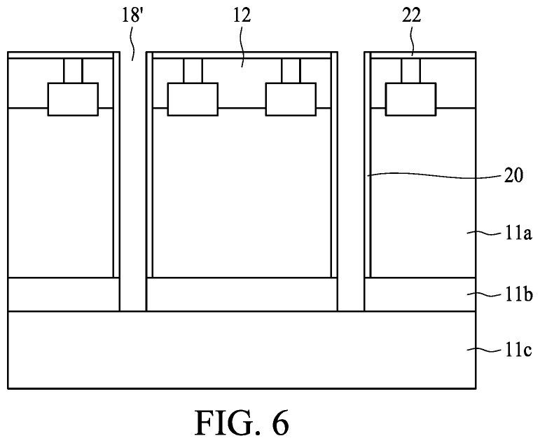

FIG. 6 is a schematic diagram of the semiconductor device 10, in accordance with an embodiment of the present disclosure. FIG. 6 may be a cross-sectional view of the semiconductor device 10 after etching the SiO layer 11b of the SOI 11. A portion of the outer liner 20 facing the SiO layer 11b of the SOI 11 at a bottom of the opening 18′ and a portion of the SiO layer 11b under the bottom of the opening 18′ may be opened by etching in order to expose the Si layer 11c under the bottom of the opening 18′. In some embodiments, forming the opening 18′ may be performed by an anisotropic dry etching method using one or a combination of gases, such as tetrafluoromethane (CF₄) gas, octafluorocyclobutane (C₄F₈) gas, hexafluorobutadiene (C₄F₆) gas, octafluorocyclopentene (C₅F₈) gas, oxygen (O₂) gas, carbon monoxide (CO) gas, argon (Ar) gas, etc., but the disclosure is not limited thereto. In some embodiments, the outer liner 20 on the barrier film 22 may be removed by the anisotropic dry etching using the barrier film 22 as a stopper for etching. The outer liner 20 on a sidewall of the through electrode 18 may remain in the Si layer 11a.

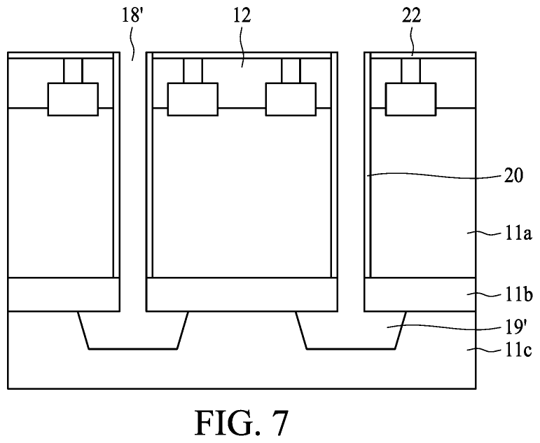

FIG. 7 is a schematic diagram of the semiconductor device 10, in accordance with an embodiment of the present disclosure. FIG. 7 may be a cross-sectional view of the semiconductor device 10 after etching of the exposed Si layer 11c. In some embodiments, the exposed Si layer 11c may be etched by an anisotropic wet etching method. In some embodiments, the anisotropic wet etching method may employ a potassium hydroxide (KOH)-based solution in order to form cavities 19′ having a depth of approximately 2 μm to 5 μm. In the anisotropic wet etching, the cavities 19′ having a trapezoid body for back bumps 19 may be formed by using different etching speeds in the Si layer 11c. Therefore, each cavity 19′ of the cavities 19′ may have a slanted sidewall and each back bump 19 may be tapered toward a side opposite to the opening 18′ to form a slanted side surface of the back bump 19. In some embodiments, for etching to form cavities 19′, an isotropic wet etching method or an isotropic dry etching method may be used instead of the anisotropic dry etching method. In some embodiments, a shape of cavities 19′ may be different depending on the etching method. The outer liner 20 may remain on the sidewall of the opening 18′.

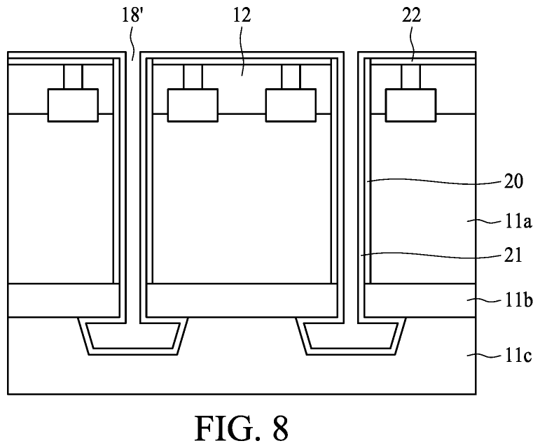

FIG. 8 is a schematic diagram of the semiconductor device 10, in accordance with an embodiment of the present disclosure. FIG. 8 may be a cross-sectional view of the semiconductor device 10 after formation of an inner liner 21 on an inner wall of the opening 18′, the cavity 19′ and the barrier film 22. In some embodiments, the inner liner 21 may be a laminate film including a SiO film of 0.3 μm thickness on a SiN film including a thickness of 0.2 μm by an atomic layer deposition (ALD) method. The SiN film may prevent copper diffusion into the Si layer while filling copper in the opening 18′ and the cavity 19′. In some embodiments, a thickness of the SiN film may be small enough to prevent an increase of parasitic capacitance between the through electrode 18 and an adjacent through electrode. In some embodiments, the SiO film may be formed to complement the thickness of the SiN film. In some embodiments, the SiO film may be inferior to the SiN film in preventing the copper diffusion, while the SiO film may be superior to the SiN film in preventing the parasitic capacitance.

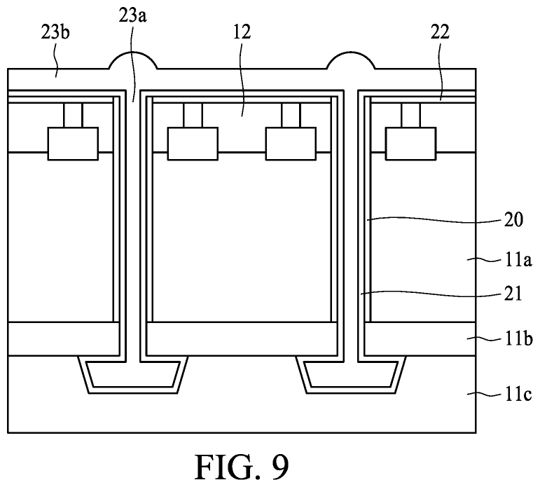

FIG. 9 is a schematic diagram of the semiconductor device 10, in accordance with an embodiment of the present disclosure. FIG. 9 may be a cross-sectional view of the semiconductor device 10 after applying of a conductive material in the opening 18′ and the cavity 19′. In some embodiments, a conductive material may be filled by copper plating. In some embodiments, copper plating may be performed by a bottom up copper plating method after applying the atomic layer deposition (ALD) to introduce a barrier layer 23a (e.g., tantalum (Ta) and/or tantalum nitride (TaN)) and a seed layer 23b (e.g., copper) on an inner wall of the opening 18′ and the cavity 19′. In some embodiments, electron beam-induced deposition, copper deposition, or melted metal filling may be used in place of the bottom up copper plating method.

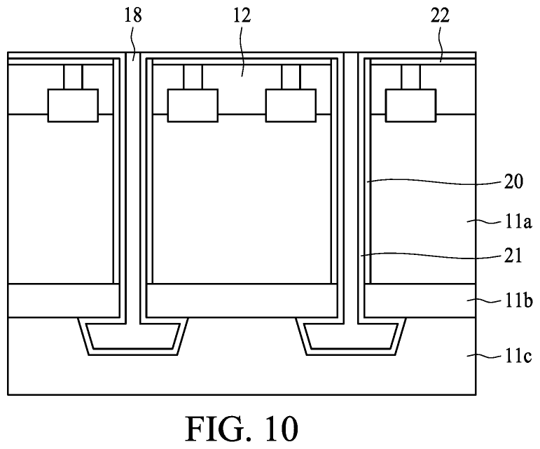

FIG. 10 is a schematic diagram of the semiconductor device 10, in accordance with an embodiment of the present disclosure. FIG. 10 may be a cross-sectional view of the semiconductor device 10 after removal of the copper from the barrier film 22. In some embodiments, the copper on the barrier film 22 may be removed by chemical mechanical planarization (CMP). In some embodiments, a part of the inner liner 21 may remain over the barrier film 22 to cover the element region 12. Therefore, through electrodes 18 may be formed to fill the opening 18′ and the cavity 19′.

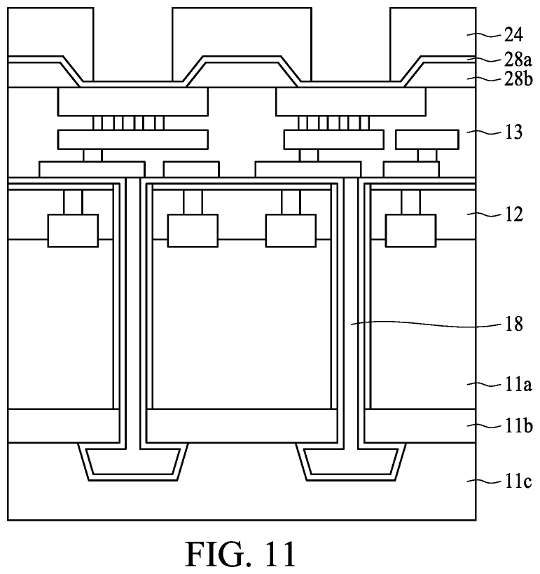

FIG. 11 is a schematic diagram of the semiconductor device 10, in accordance with an embodiment of the present disclosure. FIG. 11 may be a cross-sectional view of the semiconductor device 10 after forming a photoresist 24 for some front bumps. In some embodiments, a wiring region 13 may be formed on the barrier film 22 on the element region 12. A patterned passivation layer 28b and barrier-seed layer 28a comprising a barrier layer (e.g., a titanium (Ti) layer having a thickness of 15 nm) and a seed layer (e.g., a copper (Cu) layer having a thickness of 200 nm) may be formed on a top surface of the wiring region 13. After forming of a photoresist 24 for some front bumps, a front bump formation area on the photoresist 24 may be opened to expose the barrier-seed layer 28a. In some embodiments, a thickness of the photoresist 24 may be approximately 50 μm, but the disclosure is not limited thereto.

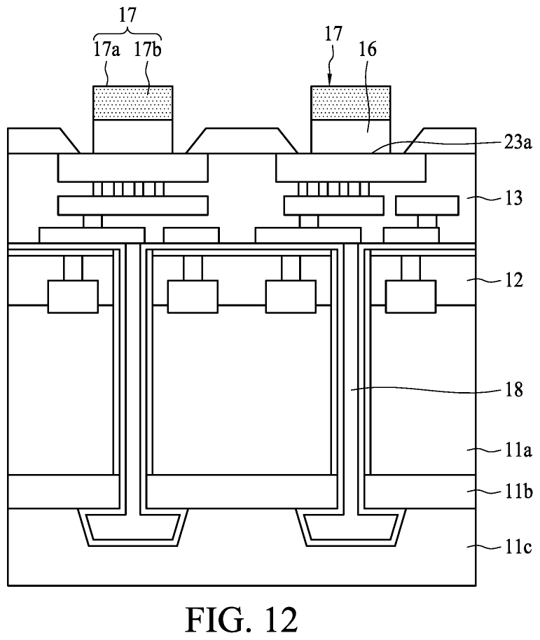

FIG. 12 is a schematic diagram of the semiconductor device 10, in accordance with an embodiment of the present disclosure. FIG. 12 may be a cross-sectional view of the semiconductor device 10 after formation of front bumps 16. The front bumps 16 may be formed by copper plating on the exposed barrier-seed layer 28a. In some embodiments, a thickness of the front bump from the copper plating may be approximately 10 μm. In some embodiments, after copper plating, the connection layer 17 may be continuously patterned and formed by spin coating, CVD (chemical vapor deposition) process or PVD (physical vapor deposition) process, but the disclosure is not limited thereto. The connection layer 17 may include a patternable material 17a with conductive particles 17b, and the patternable material 17a may have a thickness of 18 μm. In some embodiments, the patternable material 17a may be patternable and formed on the front bump 16, and the conductive particles 17b may comprise copper (Cu), nickel (Ni), gold (Au), or silver (Ag), but the disclosure is not limited thereto. After removal of the photoresist 24 using a plasma ashing and an ammonia (NH₃)-based solution, the exposed barrier-seed layer 28a may be removed with a phosphoric acid solution while using the front bumps as a mask.

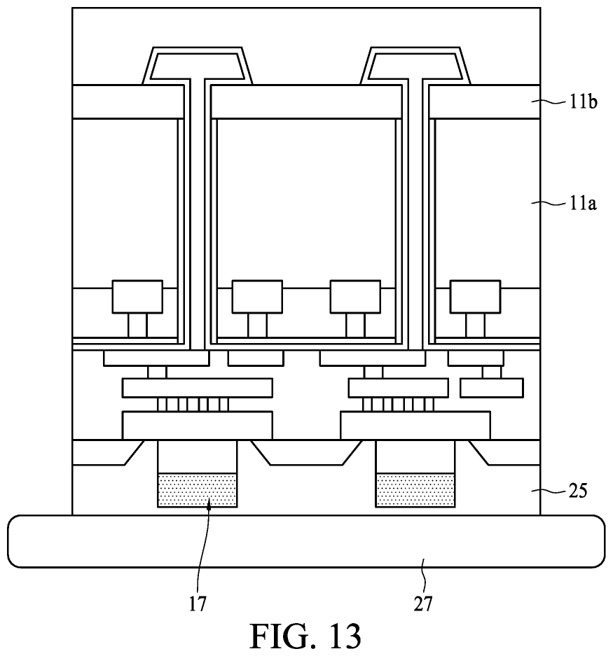

FIG. 13 is a schematic diagram of the semiconductor device 10, in accordance with an embodiment of the present disclosure. FIG. 13 may be a cross-sectional view of the semiconductor device 10 after applying a temporary carrier 27 on the semiconductor device 10. In some embodiments, the semiconductor device 10 may be flipped vertically. The front bumps 16 may be adhered to the temporary carrier 27 by heat-resistant adhesive material 25.

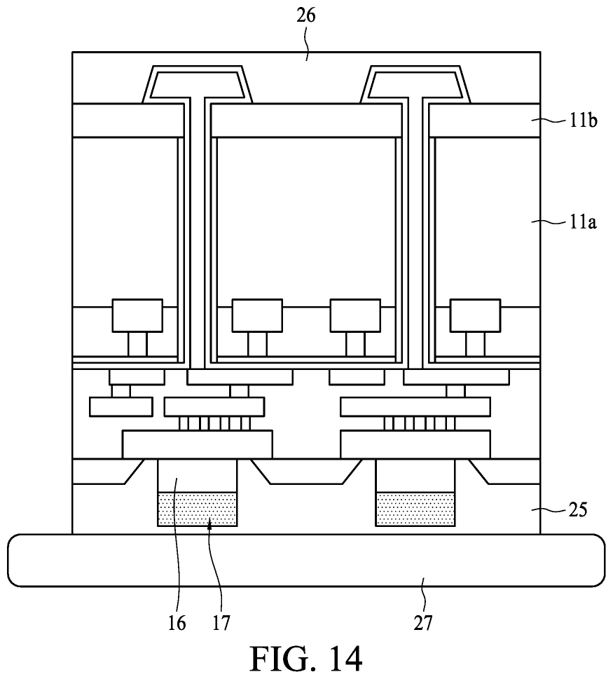

FIG. 14 is a schematic diagram of through electrodes in a semiconductor device 10, in accordance with an embodiment of the present disclosure. FIG. 14 may be a cross-sectional view of the semiconductor device 10 after removal of a portion of the SOI 11. In some embodiments, a portion of the exposed Si layer 11c may be removed by backside grinding (BG) and/or chemical mechanical polishing (CMP), but the disclosure is not limited thereto. In some embodiments, a thickness of the portion of the exposed Si layer 11c for removal may be controlled to protect the through electrodes 18 from being exposed in order to protect the Si layer 11c from copper contamination from the through electrodes 18. Therefore, a residual silicon layer 26 may remain after the removal of the portion of the SOI 11 (e.g., the Si layer 11c). The residual silicon layer 26 may cover the back bumps 19.

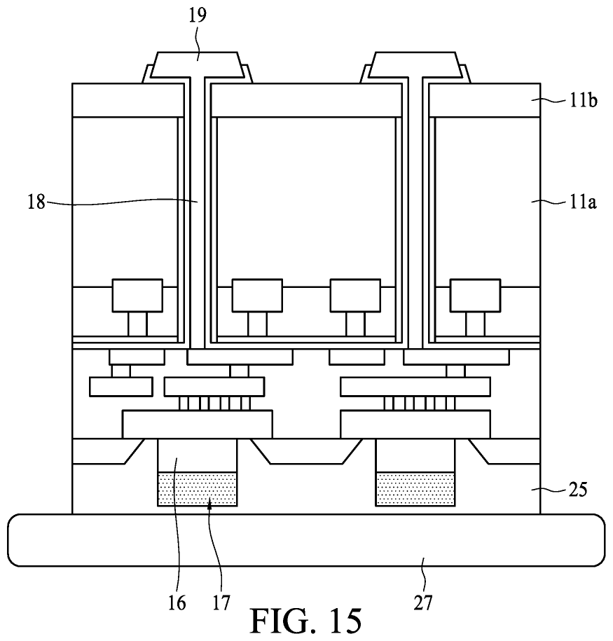

FIG. 15 is a schematic diagram of through electrodes in a semiconductor device 10, in accordance with an embodiment of the present disclosure. FIG. 15 may be a cross-sectional view of the semiconductor device 10 after exposing of back bumps 19 by Si revealing dry etching and dielectric film over-etching. In some embodiments, the residual silicon layer 26 on the SiO layer 11b may be removed. In some embodiments, a sulfur hexafluoride (SF₆) gas-based dry etching may have etch selectivity of the SiO layer 11b to the inner liner 21 of approximately 20 to 50. In some embodiments, the inner liner 21 surrounding the back bumps 19 may be etched with an etching gas to expose the back bumps 19. In some embodiments, the etching gas may be a gas mixture of fluorocarbon gas and inert gas. Etching of the inner liner 21 and the barrier 23a may be performed until exposure of the back bumps 19. In some embodiments, the back bumps 19 may be exposed by anisotropic etching. Therefore, a top surface of each back bumps 19 may be completely exposed while a portion of the inner liner 21 may remain on the back bump 19. After exposure of the back bump 19, post treatment such as alkaline solution including corrosion inhibitor may be performed to prevent copper corrosion and to remove an etching residue.

Therefore, the through electrodes in a semiconductor device according to an embodiment of the present disclosure may be formed by a method that includes: providing a substrate 11 comprising a semiconductor layer 11a, a sacrificial layer 11c and an insulative layer 11b between the semiconductor layer 11a and the sacrificial layer 11c; forming an opening 18′ through the semiconductor layer 11a and the insulative layer 11b; etching the sacrificial layer 11c to form a cavity 19′ in the sacrificial layer 11c; applying a conductive material 23 in the opening 18′ and the cavity 19′ to form a through electrode 18 with a back bump 19 (e.g., a first bump); and exposing a portion of the back bump 19. Next, a front bump (e.g., a second bump) 16 is formed on one end of the through electrode 18 opposite to the back bump 19. In addition, a connection layer 17 is patterned over the front bump 16. In some embodiments, the connection layer 17 is patternable and comprises a patternable material 17a with conductive particles 17b. In some embodiments, the patternable material 17a comprises photosensitive material. In some embodiments, the photosensitive material is a photoresist or polyimide. In some embodiments, the conductive particles 17b comprise copper (Cu), nickel (Ni), gold (Au), or silver (Ag). In some embodiments, the connection layer 17 is formed by spin coating, CVD (chemical vapor deposition) process or PVD (physical vapor deposition) process.

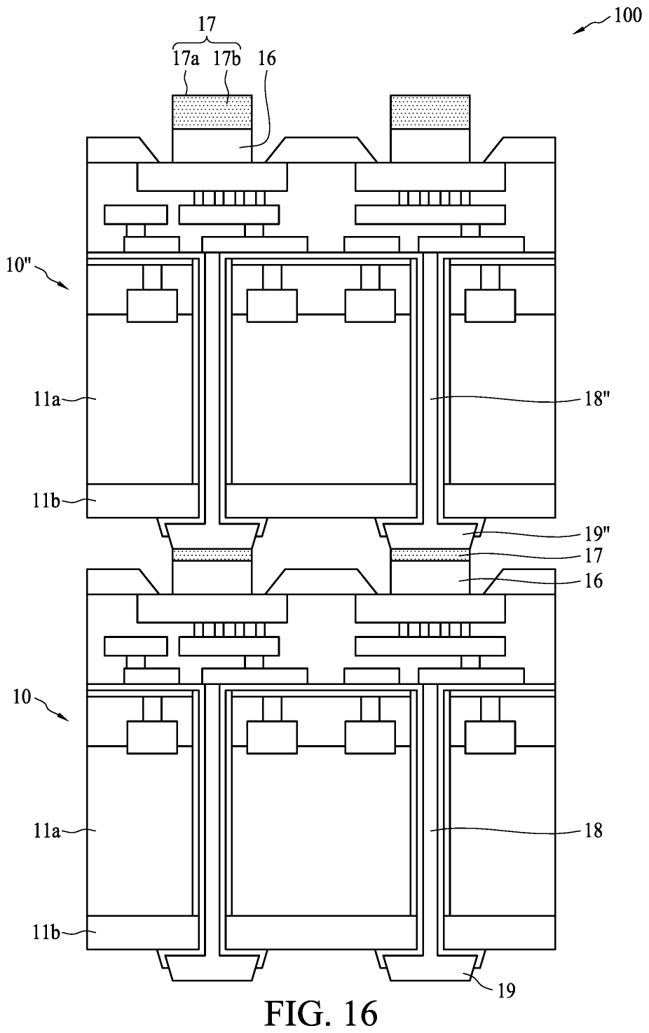

FIG. 16 is a schematic diagram of through electrodes in stacked semiconductor devices 10, 10″ of an electronic unit 100, in accordance with an embodiment of the present disclosure. FIG. 16 may be a cross-sectional view of two semiconductor devices 10, 10″ (electronic unit 100) after each back bump 19 is physically connected to each corresponding front bump 16 via the connection layer 17. In some embodiments, a cross-sectional width of the back bump 19 may be greater than a cross-sectional width of the front bump 16. In order to reduce defects due to fluidity that may cause the patternable material 17a to move toward a side wall of the back bump 19 and to drop from the patternable material 17a, the cross-sectional width of the back bump 19 may be designed to be greater than the cross-sectional width of the front bump 16.

Further, one aspect of the present disclosure provides an electronic unit. The electronic unit (as shown in FIG. 16) 100 includes at least two of the above-mentioned semiconductor devices 10, 10″. The third portion 19″ of the conductive through electrode 18″ of one semiconductor device 10″ is electrically connected to the bump 16 of the other semiconductor device 10 through the connection layer 17. The connection layer 17 is patternable. That is, the two adjacent semiconductor devices 10, 10″ as described above may be electrically connected to each other through the connection layer 17, wherein the connection layer 17 is patternable and comprises a patternable material 17a with conductive particles 17b. In some embodiments, the patternable material 17a comprises photosensitive material. In some embodiments, the photosensitive material is a photoresist or polyimide. In some embodiments, the conductive particles 17b comprise copper (Cu), nickel (Ni), gold (Au), or silver (Ag). In some embodiments, the connection layer 17 is patternable and formed by spin coating, CVD (chemical vapor deposition) process or PVD (physical vapor deposition) process.

One aspect of the present disclosure provides a semiconductor device. The semiconductor device includes a semiconductor substrate, a conductive through electrode, an insulating film, a bump and a connection layer, wherein the connection layer comprises a patternable material with conductive particles. The conductive through electrode penetrates through the semiconductor substrate. The insulating film surrounds the conductive through electrode and electrically isolates the conductive through electrode from the substrate. The bump is disposed over the conductive through electrode. The connection layer is disposed over the bump.

Another aspect of the present disclosure provides an electronic unit. The electronic unit includes at least two of the above-mentioned semiconductor devices. The third portion of the conductive through electrode of one semiconductor device is electrically connected to the bump of the other semiconductor device through the connection layer. The connection layer is patterned over the bump of the other semiconductor.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

1. A semiconductor device, comprising:
a semiconductor substrate;
a conductive through electrode penetrating through the semiconductor substrate;
an insulating film around the conductive through electrode and electrically isolating the conductive through electrode from the substrate;
a bump disposed over the conductive through electrode; and
a connection layer disposed over the bump;
wherein the connection layer comprises a patternable material with conductive particles, wherein the patternable material comprises photosensitive material.

2. (canceled)

3. The semiconductor device of claim 1, wherein the photosensitive material is a photoresist or polyimide.

4. The semiconductor device of claim 1, wherein the conductive particles comprise copper (Cu), nickel (Ni), gold (Au), or silver (Ag).

5. The semiconductor device of claim 1, wherein the connection layer is formed by spin coating, CVD (chemical vapor deposition) process or PVD (physical vapor deposition) process.

6. The semiconductor device of claim 1, wherein the conductive through electrode comprises:
a first portion in the semiconductor substrate;
a second portion protruding vertically from the first portion; and
a third portion protruding laterally from the second portion, the third portion including a side surface to define a width of the third portion.

7. The semiconductor device of claim 6, wherein the third portion of the conductive through electrode is tapered to form the side surface of the third portion in a slanted manner.

8. The semiconductor device of claim 7, wherein the third portion of the conductive through electrode is tapered toward a side opposite to the first portion of the conductive through electrode.

9. The semiconductor device of claim 8, wherein a width of the second portion of the conductive through electrode is substantially the same as a width of the first portion of the conductive through electrode, and wherein the width of the third portion of the conductive through electrode is greater than a width of each of the first and second portions.

10. The semiconductor device of claim 6, wherein the second portion, the third portion and the semiconductor substrate form a gap therebetween.

11. The semiconductor device of claim 6, wherein the first, second and third portions of the conductive through electrode are formed of the same material.

12. The semiconductor device of claim 10, wherein the insulating film comprises:
a first part between the first portion and the semiconductor substrate;
a second part in the gap; and
a third part protruding from the second part to cover a part of the side surface of the third portion.

13. The semiconductor device of claim 12, wherein a remaining part of the side surface of the third portion is not covered by the third part.

14. The semiconductor device of claim 12, wherein the first part of the insulating film has a first thickness between the first portion of the conductive through electrode and the substrate, the second part of the insulating film has a second thickness between the third portion of the conductive through electrode and the semiconductor substrate, and the second thickness is greater than the first thickness.

15. The semiconductor device of claim 14, wherein the third part of the insulating film protrudes from the second part of the insulating film with a third thickness to cover the part of the side surface of the third portion of the conductive through electrode, the third thickness being smaller than the second thickness of the second part of the insulating film.

16. The semiconductor device of claim 12, wherein the first part of the insulating film comprises a first insulating layer and a first insulating liner, the second part of the insulating film comprises a second insulating layer and a second insulating liner, the third part of the insulating film comprises a third insulating liner, and the second insulating liner is continuous with the first and third insulating liners.

17. The semiconductor device of claim 16, wherein the first part of the insulating film further comprises a fourth insulating liner between the first insulating liner and the first portion of the conductive through electrode, the second part of the insulating film further comprises a fifth insulating liner between the second insulating liner and the second portion of the conductive through electrode, the third part of the insulating film further comprises a sixth insulating liner between the third insulating liner and the third portion of the conductive through electrode, and the fifth insulating liner is continuous with the fourth and sixth insulating liners.

18. The semiconductor device of claim 17, wherein the first insulating layer has a first thickness between the first insulating liner and the substrate, the second insulating layer has a second thickness between the third portion of the conductive through electrode and the substrate, and the second thickness is greater than the first thickness.

19. The semiconductor device of claim 17, wherein each of the first, second and third insulating liners comprises a silicon nitride film, and each of the fourth, fifth and sixth insulating liners comprises a silicon oxide film.

20. The semiconductor device of claim 19, wherein the silicon nitride film is thicker than the silicon oxide film.
